(19) United States
(12) Patent Application Publication
(10) Pub. No.: US 2003/0039926 A1
(43) Pub. Date: Feb. 27, 2003

(54) Individualized decoration of the surface of a three-dimensional object

(75) Inventor: Valto Loikkanen, Helsinki (FI)

Correspondence Address: VOLPE AND KOENIG, P.C., SUITE 400, ONE PENN CENTER, 1617 JOHN F. KENNEDY BOULEVARD, PHILADELPHIA, PA, 19103, US

(73) Assignee: VTG Worldwide Oy, A Finnish Corporation, Nummela (FI)

(21) Appl. No.: 10/272,652

(22) Filed: Oct. 17, 2002

Related U.S. Application Data
(63) Continuation of application No. 09/457,497, filed on Dec. 9, 1999, now abandoned.

(30) Foreign Application Priority Data
Oct. 6, 1999 (FI) 19992157

(51) Int. Cl. G06F 17/50; G03F 7/00

(52) U.S. Cl. 430/322; 716/21

(57) ABSTRACT

Method and apparatus for creating an individualized decoration on the surface of a three-dimensional object (c). The decoration is stored in electric form. The decoration is projected and developed directly on the surface of the object. According to the individualization process of the present invention, the decoration is formed on the surface of a three-dimensional object of complex shape without the use of solid intermediate materials or mechanical operations.

### CROSS-REFERENCE TO RELATED APPLICATIONS

This application is a continuation of application Ser. No. 09/457,497, filed Dec. 9, 1999, which application is incorporated herein by reference.

### BACKGROUND OF THE INVENTION

1. Field of the Invention

The present invention relates to a method and an apparatus for producing an individual decoration on the surface of a three-dimensional object.

2. Description of the Prior Art

Currently known solutions for image transfer are based on transferring pictures, patterns and colors mechanically onto a desired surface. The methods currently used to achieve an individualized appearance, which is the final result of the present invention, include, e.g., printing, painting, heat transfer labeling, IMD (In Mould Decoration) and laser impression. The level of definition of patterns, pictures or colors produced by utilizing these methods, even when the best equipment available is used, is not comparable with the final result achieved by the technique of the invention. A significant further problem with current techniques is that of producing images or colors on all surfaces of a three-dimensional object by a single treatment.

When prior-art methods are used for individualizing objects, the costs arising from the individualization are also unreasonably high. Most of the costs incurred in the case of current individualization methods arise from operations carried out before the actual individualization, i.e., during preliminary preparations. The preliminary preparations include, e.g., films, screens, carrier films, printing plates and moulds prepared from the image or pattern.

Individualization accomplished by printing (e.g. traditional silk screen and packer printing) must be based on films made for each desired color separately, from which again printing plates are prepared, one for each color. In addition, each color has to be printed on the object separately, which again increases the production costs. By printing, it is never possible to achieve a level of definition corresponding to reality because images, patterns and colors are printed on the surface of the product as a raster, in other words, the picture consists of tiny dots. As the size of the printing lot increases, the printing costs decrease, which means that individualizing small numbers of objects is excessively expensive.

On objects individualized by painting (manually, e.g., using a paint brush, by spray-painting, using a painting robot), it is never possible to achieve a level of accuracy corresponding to reality because of the limitations of the painting techniques. In individualization by painting, the same problem is encountered as in printing; individualizing single objects is a slow business and the costs are high.

Heat Transfer Labeling is based on a heat assisted printing technique in which the desired image or color or color combination is brought by means of a carrier film onto the surface of the object to be printed, whereupon a heated metal or silicone tool is applied to transfer the desired marking permanently by the application of heat to the surface of the object. Heat transfer labeling is used especially for the individualization of plastic products.

Heat transfer labeling allowed simultaneous printing of eight colors at a time, which was a step forward in object individualization by printing methods. However, for heat transfer labeling to be profitable, large production series are required because the carrier films must be prepared separately for each object. Although heat transfer labeling allows the use of scanned images or images drawn on a monitor, the image or pattern still always has to be transferred separately to a carrier film. Besides, sharp edges cannot be accomplished by the heat transfer labeling technique, which is another limitation regarding individualization of objects.

IMD (In Mould Decoration) is a printing method whereby the surface decoration (text, image, colors, patterns) to be produced on an object is already created in conjunction with the injection molding process forming the object. The IMD technique brings cost savings to the manufacturing enterprise as the object and its individualization are produced at once. IMD printing can also be applied to three-dimensional surfaces, and it allows the combination of seven colors at a time. A problem with IMD printing is that the images or decoration are created on mass products at the manufacturing stage, which means that, when selecting a product, the customer cannot personally define the decoration to be provided on the object. The IMD technique cannot be applied to old molds; instead, new molds have to be prepared for each printing task, which again increases the costs. The problem with the IMD technique is the same as with heat transfer labeling, i.e., sharp edges disrupt the printing.

Laser impression is based on the use of an Nd-YAG beam, which is directed at an object by using two computer controlled mirrors. When the beam hits the object, a thermochemical reaction takes place on its surface. Objects can be marked by creating on their surface a trace or a color differing from the normal color of the object. However, the desired coloring agent must be mixed in the plastic in the raw material production process, which means that, in view of industrial mass production, distinctive coloring of single objects is impossible. Laser impression is a practical method when large series of products are to be marked or when the imprint is required to have a good resistance to wear. However, laser impression is subject to the same problems as other individualization methods currently used: limitations regarding the use of colors and unreasonable costs of making imprints on single objects.

### SUMMARY OF THE INVENTION

The present invention is based on the fact that solid objects of complex shape made of any known materials can be treated with a photo-sensitive emulsion, whereupon the surface of the object can be exposed using an apparatus as provided by the invention to produce an image created or selected by a customer directly from the memory of a computer, in other words, the object can be individualized exactly as the customer wishes. The invention can be utilized in all lines of business using industrial manufacturing because the method described in the invention is applicable to all known solid materials and all shapes of objects.

The technique forming the basis of the invention, i.e., object individualization method is as follows. Three-dimensional known solid materials of complex shape are given a surface decoration by an optical method by exposing, using an apparatus as provided by the invention, the surface of a three dimensional solid object treated with a photo-sensitive substance so as to produce a desired image on the surface directly from the memory of a computer. After the exposure, the object is treated with chemical substances known in photography; a developer, a stop bath and a fixer. Finally, the surface of the object can be finished by a suitable method to give additional protection, e.g., by varnishing.

In particular, the method and apparatus of the invention are characterized by what is presented in the characterization part of claim 1.

According to the individualization process of the present invention, a decoration, which may consist of a picture, pattern or coloring or a combination of these, is formed on the surface of a three-dimensional object of complex shape without the use of solid intermediate materials or mechanical actions. According to the invention, the pictures, patterns and colors formed on the surface of the three-dimensional solid object of complex shape and treated with a photo-sensitive emulsion are reproduced exactly in the desired form without limitations regarding, e.g., the reproduction of sharp edges. When the individualization method of the invention is used, the costs arising from object individualization are exactly the same regardless of whether a single object or a large series is treated. As stated above, this is not possible when methods known at present are used.

### BRIEF DESCRIPTION OF THE DRAWINGS

In the following, the invention will be described in detail by the aid of examples with reference to the drawings, wherein

FIG. 1 presents an example customer who wants to buy a product manufactured by an example enterprise,

FIG. 2 presents the example customer selecting the product he/she wants,

FIG. 3 presents the example customer individualizing the desired product by using a browser-based graphics program utilized in the invention or individualizing the product with a picture or pattern obtained from other sources and transferable in electronic form,

FIG. 4 presents the example customer confirming the product individualization and entering an order for the product,

FIG. 5 illustrates the transmission of information regarding the product ordered by the example customer to the manufacturing enterprise's data base,

FIGS. 6-7 illustrate the individualization process of the invention, and

FIG. 8 presents a diagram representing the ordering and individualization system of the invention.

### DETAILED DESCRIPTION O F THE PREFERRED EMBODIMENTS

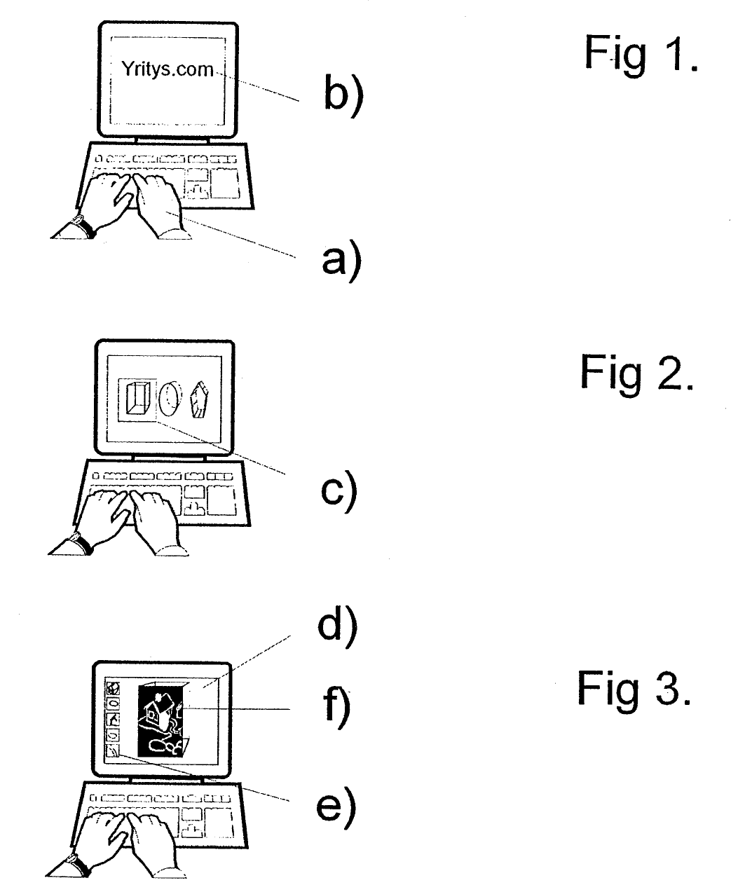

FIG. 1 depicts a customer A, who wishes to buy a product from a manufacturing enterprise. The customer, who may be a private person or a company placing an order with a subcontractor, browses the manufacturing enterprise's Internet pages b or other selection facility, using, for example, an Internet local area network, a wireless communication terminal provided with a WAP browser, a digital TV set or other graphic communication means.

FIG. 2 illustrates a situation where the example customer selects the de sired product c in the Internet pages (or other selection facility as mentioned above) of the enterprise. The product may be a three-dimensional object of any size and shape, sold by the manufacturing enterprise.

In FIG. 3, the product is being viewed by the customer in a browser-based graphics program d (or some other selection facility mentioned in the description of FIG. 1), which contains various pictures, patterns and colors e ready to be selected. The customer can himself place any of these elements on the surface f of the product. The browser-based graphics program is available through a data server maintained by the manufacturing enterprise, so it is not necessary for the customer to have that program in his own computer or other apparatus.

If the customer wishes, he may utilize the technical operating characteristics of the graphics program and himself draw the desired patterns or images on the product. The customer can also place ready-made pictures or patterns onto the product from outside the program, e.g., from the Internet, from his own computer storage and so on, i.e., any picture or pattern that can be transmitted in an electric form. The customer may also be provided a design and layout service by the manufacturer of the product.

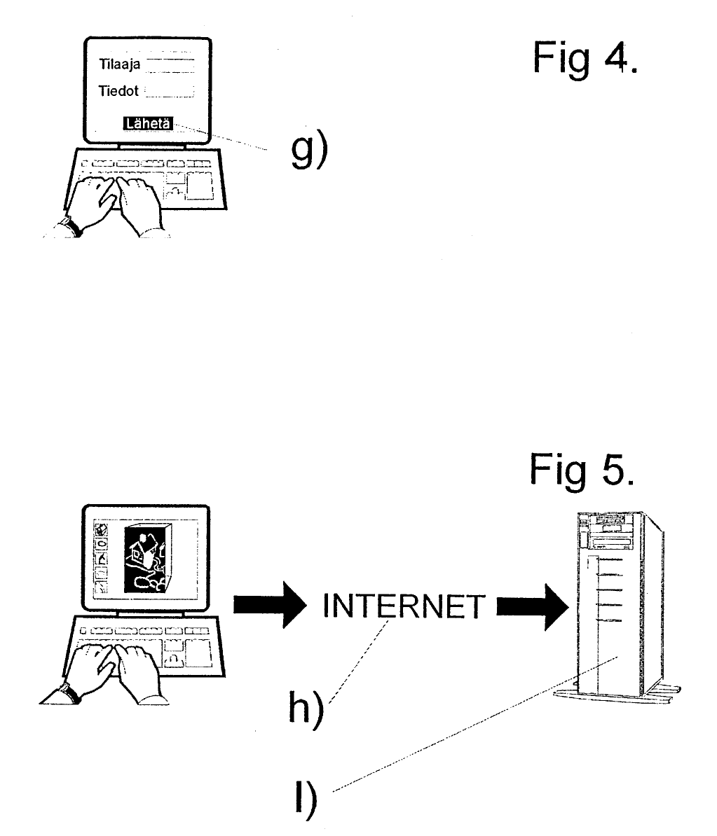

FIG. 4 illustrates a customer confirming g and/or paying for a product individualization which he has selected or designed or which has been designed for him. However, the product need not necessarily be paid for at this stage because, e.g., a customer representing an enterprise may just place an order for the product, for which he will be charged after the product has been delivered.

FIG. 5 illustrates the transmission of the information related to the customer's order (details of the product wanted, images, patterns and materials as well as name and address and possible invoicing information) over telecommunication networks h to the order system of the manufacturing enterprise. The information is stored in the memory of a server in the manufacturing enterprise.

The specimen ordered by the customer may be launched into the production process as a solid prefabricated body or it may be prepared before entry into the individualization process from raw materials, e.g., by injection molding. Some (e.g. metallic) objects may be sprayed with a primer (e.g. varnish) to render the surface structure of the object more workable. However, the use of a primer is not essential. Objects made of certain materials (e.g. plastic) can be treated directly with a photo-sensitive emulsion.

The computer identifies the object being entered into the individualization process and associates the object with the decoration specified by the customer. The manufacturing enterprise may also provide an assortment of three-dimensional objects of different shapes (manufacturing enterprise's product range) in a pre-finished condition (treated with primer, e.g., varnish, or photo-sensitive emulsion), ready to be passed into the actual individualization process. The computer selects the object or objects to be produced next. The order of production may be based on a predetermined sequence or directly on the sequence in which the objects have been ordered.

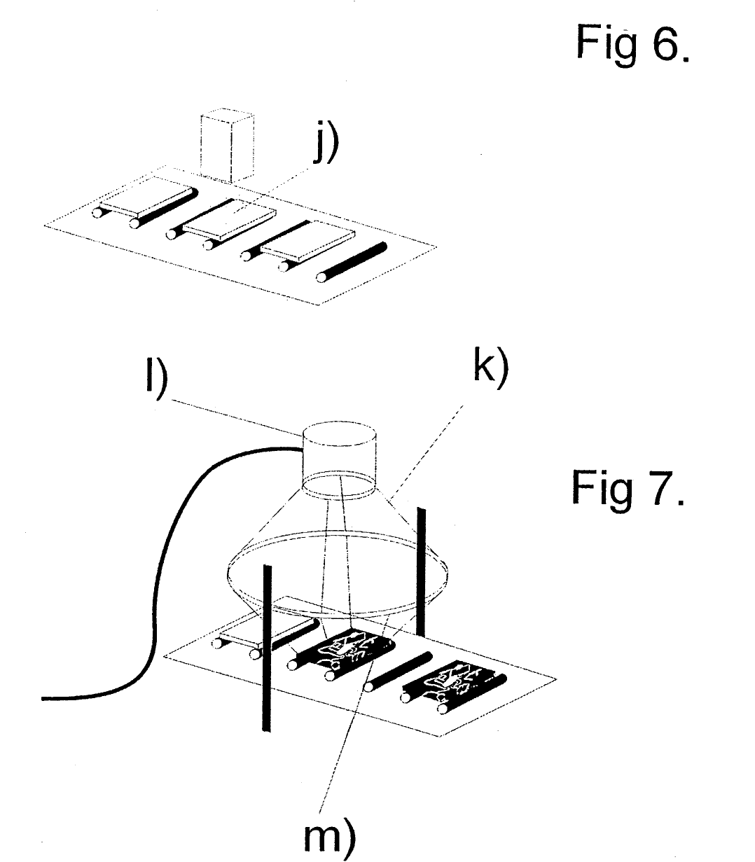

FIG. 6 illustrates the beginning of the individualization process of the invention with the object surface being sprayed with a photo-sensitive emulsion j.

FIG. 7 illustrates the exposure k of an object by means of an apparatus l according to the invention to project an image or pattern as desired by the customer to the object surface treated with a photo-sensitive substance directly from a picture file stored in the manufacturer's computer.

The shapes of the surfaces of the objects to be individualized are stored in a database maintained by the manufacturing enterprise. Based on the three-dimensional shapes of the objects, various image processing filters have been created in an automated image processing program to minimize distortion of the final result of individualization. In the image processing program, the image or pattern is processed before being projected onto the surface of the three-dimensional object. Using image processing filters, it is possible to minimize geometric distortions of the image or pattern arising from fitting a two-dimensional image or pattern onto a three-dimensional surface.

If necessary, the exposure of the object can be implemented using a somewhat different technical solution than in currently known exposure methods. The lens m of the apparatus of the invention may be specially shaped or it may be larger than the object to be exposed, in which case the image or pattern projected by the apparatus is diminished as it falls on the object. As the size of the image or pattern is diminished in conjunction with the exposure, the image definition is improved and, on the other hand, the same exposure is also sufficient for the exposure of, e.g., vertical surfaces at once. The apparatus may also be provided with side mirrors for projecting an image, pattern or coloring onto all surfaces of a three-dimensional object during a single exposure.

Following the exposure, the production process utilizes techniques known in photography. The object is treated with a developer, the development is stopped after the lapse of a desired length of time, and finally the pattern, image and/or colors are fixed on the surface of the object. Depending on the ultimate use of the object (exposure to wear, heat, water, etc.), it can be finally provided with additional protection, e.g., by varnishing.

The object has now been finished by the manufacturing enterprise's production process, individualized in accordance with the customer's wishes. The finished object is packed and delivered to the customer in accordance with the terms of delivery agreed upon at ordering time. The individualized object may also be passed on in the production process, e.g., into an assembly stage.

The invention can be used by any production plant engaged in industrial manufacture to individualize the products manufactured in accordance with customers' wishes.

By utilizing the invention, the manufacturer of any solid three-dimensional object of complex shape made of any known material can individualize the product exactly as the customer wishes. As compared with any known technique, this individualization system produces a product individualized according to customer's wishes accurately and, considering the accuracy, quickly. The manufacturing costs are low and always remain the same regardless of whether the product is produced as a single piece or in larger numbers. Moreover, the manufacturing enterprise has no need to keep completely finished products in store as the product is fabricated upon the customer's order.

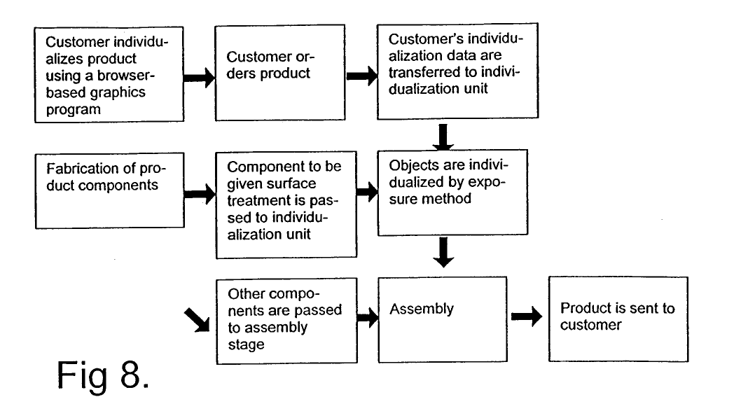

This objective is achieved by utilizing an ordering and individualization system according to the invention, the overall structure of which is best illustrated by FIG. 8.

It is obvious to the person skilled in the art that different embodiments of the invention are not restricted to the ordering and manufacturing process presented in the above example, but that they may be varied in the scope of the claims presented below. The network based method of the invention for ordering, fabricating and individualizing a product can also be utilized in other systems besides the ordering and fabrication system according to the manufacturing process described in this example.

The individualization method of the invention can be utilized, e.g., by a designer working for a manufacturing enterprise. The designer can use a browser-based graphics program to produce object decoration designs for the enterprise. The fabrication and individualization of the objects are then implemented by the individualization method of the invention.

The method for individualizing a picture, pattern or colors to be transferred to the surface of a three-dimensional object can therefore be utilized in separation from the ordering and fabrication system of the invention.

1. Method for creating an individual decoration on a non-planar surface area of a three dimensional object (c), characterized in that
the decoration has been stored in an electronic form,
shapes of surface areas of objects to be decorated have been stored in an electronic form,
the object to be decorated is viewed by a user with a graphics program, wherein the graphics program includes one or more elements that are selected by the user and arranged on the non-planar surface area of the electronic form of the object, thereby forming the decoration, and
the decoration is projected directly to the non-planar surface area of the object by exposing the object and developing the decoration.

2. Method as defined in claim 1, characterized in that the non-planar surface area of the object is sprayed with a photo-sensitive emulsion, whereupon the decoration is projected onto the non-planar surface area of the object and developed.

3. Method as defined in claim 1, characterized in that the decoration is projected onto the non-planar surface area of the object directly from the memory of a computer.

4. Method as defined in claim 1, characterized in that the shapes of the surfaces of the objects to be decorated have been stored in an electric form.

5. Method as defined in claim 1, characterized in that, based on the non-planar surface area shapes of the objects, to minimize the distortion of the decoration, one or more image processing filters are used in an automated image processing program, in which the decoration is filtered before being projected onto the non-planar surface area of the three-dimensional object.

6. Method as defined in claim 1, characterized in that, in the method, the object (c) to be decorated is selected from Internet pages or other computer selection facility, and that an image of the object can be viewed with elements of the decoration as they would appear if they were actually arranged on the non-planar surface area (f) of the object.

7. Apparatus for creating an individualized decoration on the surface of a three-dimensional object (c), characterized in that
the apparatus comprises a computer in whose memory the decoration has been stored in an electric form, and
devices for exposure and development, by means of which the decoration is projected and developed directly on the surface of the object.

8. Apparatus as defined in claim 7, characterized in that the computer is provided with browser software, by means of which the object (c) to be decorated is selected from Internet pages or an equivalent selection facility, and graphics software which can be used to view the object and lay out image and other elements on the surface (f) of the object.

9. Apparatus as defined in claim 7, characterized in that the apparatus comprises a lens (m) that is larger than the object to be decorated, causing the projected image to be diminished and focused when it falls on the surface of the object and making it possible to accomplish the decoration of the surfaces of the three-dimensional object by a single exposure.

10. Apparatus as defined in claim 7, characterized in that the apparatus is provided with mirrors for lateral reflection, allowing the entire three-dimensional surface to be exposed at once.

11. Method for creating an individual decoration on a non-planar surface area of a three-dimensional object (c), characterized in that:
the decoration has been stored in an electronic form,
shapes of non-planar surface areas of objects to be decorated have been stored in an electronic form,
the object to be decorated is viewed by a user with an Internet browser-based graphics program, wherein the decoration is determined by the user arranging one or more elements on the non-planar surface area of the electronic form of the object and the elements are ready-made pictures or patterns selected from Internet, and
the decoration is projected directly to the non-planar surface area of the object by exposing the object and developing the decoration.

12. A method for creating an individual decoration on a three-dimensional shaped surface of an object, the method comprising the steps of:
storing the shape of the three-dimensional surface in electronic form,
providing a graphic program that displays the electronic form of the three-dimensional surface and enables a user to define a decoration by arranging one or more elements on the electronic form of the three-dimensional surface,
storing the decoration in an electronic form,
treating the three-dimensional surface with a photo-sensitive substance,
projecting the electronic form of the decoration onto the three-dimensional surface, and
treating the photo-sensitive substance to develop and fix the decoration on the three-dimensional surface.

13. The method of claim 12, further comprising the step of filtering the decoration before the step of projecting the electronic form of the decoration onto the three-dimensional surface in order to minimize distortion.

14. The method of claim 12, wherein the one or more elements are each two-dimensional.

15. The method of claim 12, wherein the graphic program is accessed by the user through an Internet browser.
